(19) United States
(12) Patent Application Publication
(10) Pub. No.: US 2006/0028231 A1
(43) Pub. Date: Feb. 9, 2006

(54) System for manufacturing display panel, method to be used in same, and testing apparatus therefor

(75) Inventors: Akito Kishida, Tokyo (JP); Hideyuki Norimatsu, Tokyo (JP)

Correspondence Address: Paul D. Greeley, Esq.;Ohlandt, Greeley, Ruggiero & Perle, L.L.P., One Landmark Square, 10th Floor, Stamford, CT, 06901-2682, US

(73) Assignee: Agilent Technologies, Inc.

(21) Appl. No.: 11/158,992

(22) Filed: Jun. 22, 2005

(30) Foreign Application Priority Data
Jul. 14, 2004 (JP) 2004-206890

(51) Int. Cl. G02F 1/13; H01L 21/66; G01R 31/00

(52) U.S. Cl. 324/770; 349/1; 438/16

(57) ABSTRACT

The system for producing a display device controlled by a formula comprises a device for producing a panel substrate, which forms a thin film of a semiconductor material and forms the drive circuits for the pixels; a testing device for testing the resulting panel substrate; and a mounting device for mounting a display vehicle containing organic EL or liquid crystal material on a tested panel substrate. The testing apparatus having the testing device determine the threshold voltage of the drive circuits of each pixel during testing and these threshold values serve as the criteria for determining the parameters for substrate manufacture of the panel substrate manufacturing device.

### FIELD OF THE INVENTION

The present invention relates to a system for manufacturing a panel substrate of an organic EL (OLED) or liquid crystal, or other flat panel display, and a manufacturing method used in this system, and, in particular, it relates to means for testing the panel substrate during the manufacturing steps prior to assembly with an organic EL or liquid crystal, and means for correcting the manufacturing parameters based on these test results.

### DISCUSSION OF THE BACKGROUND ART

Various types of quality testing are performed during the steps involved in the manufacture of a display using an organic EL or liquid crystal. So-called image testing or sensory testing whereby the picture quality of a display screen is determined during the final steps of display manufacture is often performed macroscopically because the use of a testing apparatus cannot be deemed reliable. In contrast to this, a conventional panel substrate can be tested using direct electrical or optical means during the interim stages of manufacture. Such testing uses means whereby, for instance, wiring capacity is sampled by charging and discharging to the pixel capacity (JP (Kokai [Unexamined Patent Publication]) 6[1994]-43490, JP (Kokai [Unexamined Patent Publication]) 11[1999]-9525).

However, although silicon substrates are generally used as the panel substrate that forms the drive circuit containing the thin-film transistor (TFT), amorphous silicon substrates, polysilicon substrates, and low-temperature polysilicon substrates are also used because they have a different crystal state. However, these pose disadvantages because they impose various process restrictions on panel structure, and the like; for example, amorphous silicon substrates can be easily manufactured by a low-temperature process, but the carrier mobility during device formation is low, whereas carrier mobility during device formation is high with polysilicon substrates, but the latter require a high-temperature process. In contrast to this, low-temperature polysilicon has an advantage in that crystals having a relatively high mobility sufficient for practical use can be realized by a low-temperature substrate forming process.

Laser annealing is a typical method for manufacturing a low-temperature polysilicon substrate (Nikkei Microdevice, October, 2003, No. 220, pages 102 to 103). Specifically, an amorphous silicon thin film premolded on a glass substrate is irradiated by a laser pulse in order to promote recrystallization and thereby induce polycrystallization. An excimer laser is used in many cases, but it is necessary to virtually uniformly irradiate the entire surface of a relatively large panel substrate with light. Therefore, various attempts have been made to modify the optical system that is used with the laser (JP (Kokai [Unexamined Patent Publication]) 11[1999]-125,839). Moreover, annealing devices that use visible light lasers in place of excimer lasers have recently been developed (Nikkei Microdevice, October, 2003, No. 220, pages 102 to 103).

Nevertheless, even when testing is performed by interim testing during the actual manufacture of panel substrates, there is no end to devices judged “defective” because of “color” and other irregularities during the final step of sensory evaluation. The likelihood of a product being “defective” has increased with the increase in size of displays in recent years, creating fears of a poor yield, and there is therefore a demand for improvement of the manufacturing process.

In particular, although there is no need for complete uniformity of the entire surface of the panel during production of actual display panels, two-dimensional local in-plane distribution must be uniform. Consequently, even if the panel surface area has been enlarged, when a product is judged “defective” due to color and other irregularities attributed to local in-plane irregularities on the production line, measures should be promptly implemented so there will be no further “defective” products in the production line.

### SUMMARY OF THE INVENTION

A manufacturing system that is capable of promptly responding when a defective product has been produced during the manufacture of flat panel display products with a relatively large surface area and, as a result, is capable of maintaining a sufficiently high production yield, as well as a manufacturing method to be used in the same, and a testing apparatus therefor.

The manufacturing system provided by the present invention is a system that is controlled by a formula and uses the feedback of output signals from a testing apparatus. The system comprises panel substrate manufacturing means for forming a thin film of semiconductor materials and the drive circuit for the pixels; a testing means for testing the resulting panel substrate; and a mounting means for mounting the display vehicle that contains organic EL or liquid crystal material on the tested panel substrate. The testing means determine the threshold value of the drive voltage for the drive circuit from the detected charge corresponding to each pixel during testing. This threshold value is the criterion for determining substrate manufacturing parameters during panel substrate manufacture. The system can also be constructed so that feedback is automatic.

The threshold value is the criterion for determining the parameters for forming a thin film of the semiconductor materials in the panel substrate manufacturing means. Thin-film formation usually comprises means for depositing a thin film of the semiconductor materials and a means for annealing the deposited thin film. The threshold value is provided to both of the means and can serve as the criterion for determining the parameters for performing deposition and annealing of the thin film. In the latter case, laser annealing is used as a typical annealing means and the above-mentioned threshold value is used to determine the parameters of laser annealing. For instance, by means of laser annealing, the irradiation conditions pertaining to at least part of the panel substrate are set in accordance with the threshold value of the drive circuit of each pixel that has been tested such that they differ from the irradiation conditions pertaining to the other parts.

A typical drive circuit on the display substrate that is the object of the present invention (also panel substrate hereafter) comprises thin-film transistor elements for switching the pixels on and off; capacitors connected to the gate of the thin-film transistor elements; and source connectors coming from the power source supply lines on the panel substrate and connected to the drain side of the thin-film transistor elements. The testing means of the system comprise means for retaining the charge of the capacitors and means for detecting the charge that flows out from the capacitors and determining the threshold value when the potential of the source connectors gradually changes. For instance, the testing means detects the charge flowing from the capacitors through data lines that are set up such that they are connected to the drive circuit on the panel substrate. In this case, the drive circuit is connected to the gate and has additional load capacity for receiving the charge flowing out from the capacitors.

Furthermore, the present invention provides a method for manufacturing display apparatuses that is to be used in the above-mentioned manufacturing system. The manufacturing method of the present invention comprises steps for manufacturing a panel substrate, including steps for forming a thin film from semiconductor materials that are controlled by a formula and steps for forming a drive circuit for pixels; testing steps for interim testing of the resulting panel substrate; and mounting steps for mounting the display medium on the tested panel substrate. The testing steps comprise a step for determining the threshold value of the drive voltage of each drive circuit of the pixels during testing and a step for providing the determined threshold value information to the panel substrate manufacturing means such that it serves as the criterion for determining the manufacturing parameters during panel substrate manufacture. The steps for the formation of a thin film of the semiconductor materials comprise a step for the deposition of semiconductor materials and a step for the laser annealing of the deposited semiconductor materials, and the threshold value is used as the criterion for determining the parameters in at least the laser annealing step. The threshold value information can also be provided by an automatic feedback means during the process whereby this information is provided to the panel substrate manufacturing means.

The drive circuit that serves as the object of the above-mentioned method comprises thin-film transistor elements for switching the pixels on and off; capacitors connected to the gates of the thin-film transistor elements; and electrical source connectors coming from the power supply lines on the panel substrate and connected to the drain side of the thin-film transistor elements, and the testing steps comprise a step for retaining the charge on the capacitors; a step for gradually changing the potential of the source connectors and allowing charge to flow from the capacitors; and a step for detecting the charge flowing out from the connectors and determining the threshold value.

It is important that charge does not flow in and out from the outside at the position of the gate of the first thin-film transistor elements when varying the potential of the electrical source connectors. Consequently, the change in potential should be relatively gradual rather than relatively sudden.

Furthermore, the present invention provides a testing apparatus for the above-mentioned display device manufacturing system. This testing apparatus is an apparatus for testing the operation of drive circuits corresponding to each pixel on the display panel substrate. Drive circuits corresponding to each pixel are set up on the display substrate. These drive circuits comprise first thin-film transistor elements for switching the pixels on and off; capacitors connected to the gate of the first thin-film transistor elements; and electrical source connectors that extend from the power supply lines on the display panel substrate and are connected to the drain side of the first thin-film transistor elements. The testing apparatus comprises means for retaining the charge at each capacitor; means for gradually changing the potential of these electrical source connectors and allowing charge to flow out from the capacitors; means for detecting the charge flowing out from the capacitors and determining the threshold value of the drive voltage of the first thin-film transistor; and means for outputting the determined threshold value information.

The drive circuits have a second thin-film transistor in between the first thin-film transistor gate and the data lines on the display panel substrate and the means for detecting the charge comprise means for switching and controlling the second thin-film transistor such that the charge flowing out from the capacitors is led to the data lines. The second thin-film transistor gate is constructed so that it is connected to the gate line on the display panel substrate and the second transistor is controlled through the gate line. In one example, the drive circuits are constructed so that the first and second thin-film transistors are p-type gates; they have additional load capacity that is connected between the first thin-film transistor gate and the pixel electrode on the drain side of the first thin-film transistor such that the charge that is flowing out is received; and they comprise means for controlling the first thin-film transistor such that the load capacity is reset during the first step. In another example, the drive circuits are constructed with the first and second thin-film transistors being n-type gates and have means for control such that the potential of the gate lines is always is kept constant.

By means of the present invention, it is possible to play a role in effectively and promptly modifying the manufacturing process in order to prevent color regularities and other local in-plane irregularities during the final stages of manufacture and thereby improve the final product yield by efficiently feeding back information of the drive circuits recognized by an interim testing means of the manufacturing system.

### BRIEF DESCRIPTION OF THE DRAWINGS

FIG. 1 is a block diagram showing the entire manufacturing process of the manufacturing system of the present invention.

FIG. 2 is a drawing showing (a) the typical structure and (b) the time chart for testing a voltage drive-type drive circuit.

FIG. 3 is a drawing showing (a) the typical structure and (b) the time chart for testing a current drive-type drive circuit.

FIGS. 4(a) and (b) are diagrams showing specific examples of the structure of a laser annealing apparatus by different methods.

### DETAILED DESCRIPTION OF THE PREFERRED EMBODIMENT

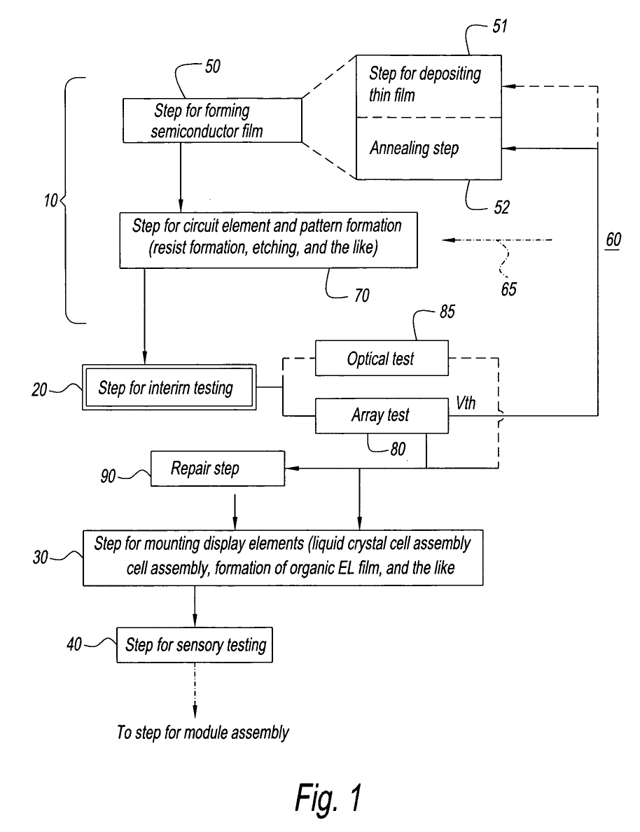

The system for manufacturing a display panel, the method to be used in the same, and the testing apparatus therefor that are the preferred embodiments of the present invention will now be described in detail while referring to the attached drawings. FIG. 1 shows a block diagram of the entire manufacturing process used by the manufacturing system of the present invention. The present invention is characterized by both the manufacturing system and the method to be used in the same, but for convenience, the present invention will be explained through a description of the method. System construction can be described as the means relating to each step.

The manufacturing process of the present invention roughly comprises a first step 10 for manufacturing panel displays; a testing step 20, which is the interim step; a mounting step 30 for assembling a liquid cell, or forming an organic EL element film, on the resulting substrate; and a sensory testing step 40 for testing the completed panel substrate assembly. The substrate assembly that has passed through sensory testing step 40 is then moved to the module assembly step.

Panel substrate manufacturing step 10 further comprises a semiconductor film forming step 50 and the next pattern forming step 70. Semiconductor film forming step 50 further comprises a step 51, for instance, for depositing silicon or another semiconductor material by low-temperature growth and a step 52 for promoting crystallization by an annealing treatment of the deposited thin film. Thin-film deposition at a low-temperature is performed, for instance, by plasma CVD film formation. A glass substrate is usually used as the substrate for forming a film from the semiconductor materials. Although a relatively expensive glass substrate must be used when annealing at a high temperature, the substrate treatment can be performed at a relatively low temperature (for instance, approximately 400° C. or lower) by laser annealing or another such method; therefore, a relatively inexpensive substrate can be used.

The semiconductor material deposited on the substrate is usually amorphous and does not have sufficient mobility for panel substrate manufacture. Therefore, it is necessary to anneal the deposited substrate by annealing step 52 to promote crystallization to polycrystallization (polysilicon) and thereby increase the mobility. In general, a mobility of 100 cm²N·s or higher is necessary with n-type polysilicon and of 50 cm²N·s or higher is necessary with p-type polysilicon. Excimer laser (for instance, XeCl, KrF) or visible light (for instance, green light solid lasers; wavelength of 532 nm) laser annealing means are used for the annealing treatment because of the requirement for low-temperature substrate treatment.

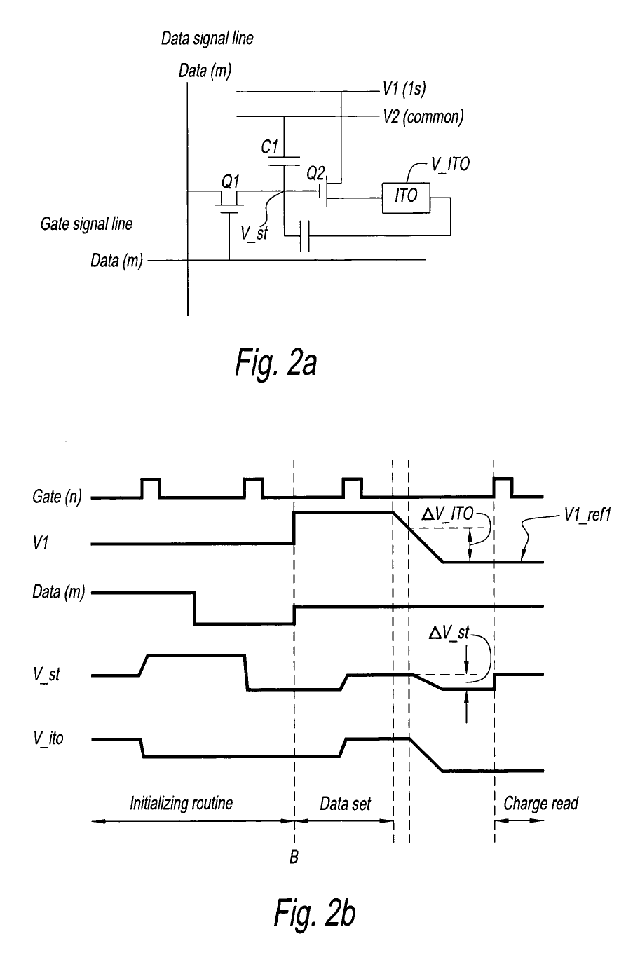

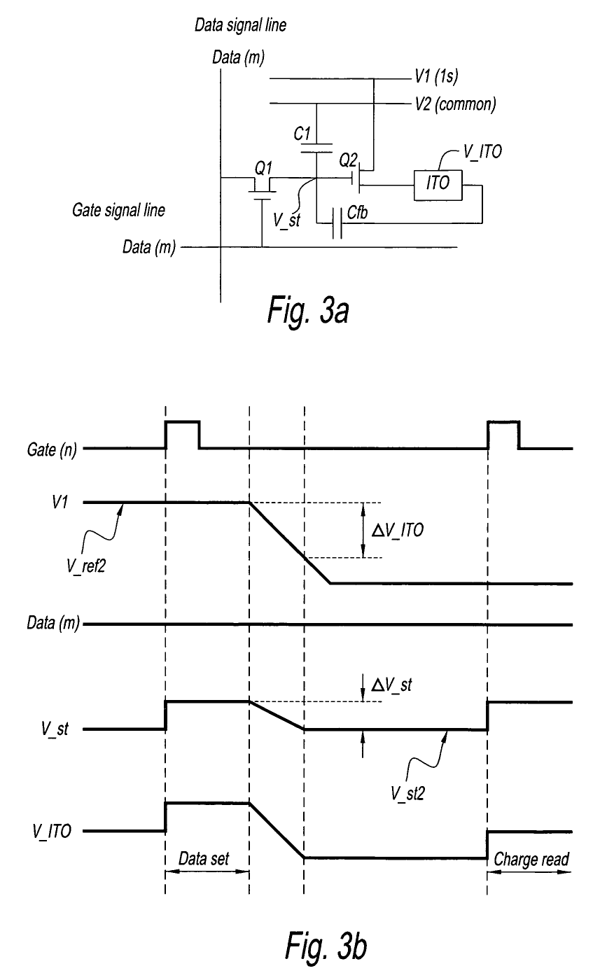

Then, the necessary circuit elements and patterns are formed on the semiconductor film that has been formed. By means of this circuit element and pattern formation step 70, for instance, a resist is formed by employing a pre-determined mask on the semiconductor thin film, and the necessary circuit elements and patterns are formed by etching treatment using conventional photolithography means. The drive circuits that drive the display elements by voltage modulation or current modulation are formed on the semiconductor thin film by this step. As will be described later, drive circuits corresponding to each pixel comprise thin-film transistor elements for switching operation (refer to FIGS. 2 and 3).

Interim testing step 20 is the step for testing only those panel substrates that have successfully completed the above-mentioned preceding steps during the interim stages of manufacture. By means of the manufacturing system or manufacturing method of the present invention, an array testing step 80 primarily conducts optical tests 85 by electrical means as necessary during the interim testing step. Optical testing 85 usually involves inspecting the wiring of the power source or signal transmission path on the drive circuit or substrate and checks for the presence of impurities on the substrate using a CCD camera or other type of image analysis.

Array testing 80 also involves confirming the electrical operation of drive circuits and simultaneously sampling the operating threshold voltage Vth of the thin-film transistor elements directly related to pixel switching operations. The sampling means will be described later. For instance, when it has been confirmed that the operating threshold Vth is not within a pre-determined range and is “anomalous,” the testing apparatus (not illustrated) can feed this result back from 60 to the preceding film forming step 50. In another case, even if the operating threshold value Vth is within a pre-determined range, this information can be similarly fed back if the fluctuations are relatively large. That is, an advantage of the present invention is that the quantitative information of the operating threshold value Vth can be fed back, and using this quantitative feedback information at the film-formation step is very effective. Of course, it is also possible to confirm that there is a quantitative problem by using the “normal” or “anomalous” status of the operating voltage Vth and referring to this information during the step for forming the circuit elements and patterns after step 50 for forming the film, as shown as another possibility in FIG. 1 (reference number 65).

Usually the preferred range is 0.5 to 5 V with an n-type polysilicon thin-film transistor and −0.5 to −5 V with a p-type polysilicon thin-film transistor. By means of the testing apparatus of the present invention, the threshold value that serves as the criterion can be changed by the user. For instance, the above-mentioned range can be set as the “normal” range, but it can also be set to a narrower range (for instance, 0.7 V to 2 V for a n-type thin-film transistor and −0.7 V to −2 V for a p-type thin-film transistor). When a threshold voltage outside this criterion range is detected, the testing apparatus can output this as signals indicating an anomalous status, or it can output the detected numbers without further treatment, and provide this output as feedback 60 to the preceding thin-film deposition step 51 or the annealing step 52. This feedback 60 is automatically performed by means of the appropriate radio or wireless communication means (LAN, and the like) between apparatuses and should be referred to by thin-film deposition step 51 or annealing step 52. However, it is not necessarily automated and can be performed by human operators.

When a defective site is discovered by interim testing step 20, the necessary corrections are made at a repair step 90 if this defective site can be repaired at repair step 90. There are various methods known as repair methods, and one example is pattern repair, and the like, by laser irradiation.

The panel substrate that has been repaired or tested is then moved to the next step of mounting. By means of this mounting step for the display element, the panel substrate and liquid crystal cell are assembled or an organic EL thin film is formed on the panel substrate. As a result, a liquid crystal display or an organic EL device is completed as the display device. A sensory testing 40 is conducted on the completed display device in the final step. By means of sensory testing 40, a person directly inspects the display status macroscopically and confirms that there are no color or other irregularities. As a result of confirmation, the devices that have been judged of good quality are moved to the next module assembly process.

The main characteristic of the present invention is that the testing means in array testing 80 are means for optimizing semiconductor thin film 50 based on the feedback of signals relating to the threshold value information from the testing apparatus. This will now be described in further detail.

FIGS. 2 and 3 are figures showing a typical structural example of a voltage drive-type drive circuit and a current drive-type drive circuit (refer to (a) in each) and a time chart of the test (refer to (b) in each figure). The testing apparatus and sampling of operating threshold value Vth will be described while referring to these figures.

The voltage drive-type drive circuit in FIG. 2 uses n-type transistors Q1 and Q2. A capacitor Cfb is first reset as a first setting routine in the first step of the test. Specifically, the gate of transistor Q2 is turned on once again and capacitor Cfb is reset with source supply line V1 in a state of zero potential. This is done in order to eliminate any detrimental effect from the charge present from the start on capacitor Cfb and for high-precision measurement of charge. Next, charge supply voltage V1 is fed to transistor Q2. Furthermore, the gate of transistor Q1 is turned on, transistor Q2 is turned on by a predetermined voltage from data signal line Data (M), this voltage is applied to retaining capacitor C1, and transistor Q1 is turned off. V_ITO shows that the voltage at the electrode, and the voltage at capacitor Cfb are saturated and are brought to a constant state by maintaining this status for a predetermined time. Transistor Q2 is also turned off.

Voltage V1 gradually falls from this state. Voltage V_ITO will not change until V1 and V-ITO become the same. However, when the difference between the voltage V1 and V-st exceeds the threshold voltage Vth of transistor Q2, that is, when V1 becomes a lower voltage than V_ITO, transistor Q2 is turned on, and thereafter V_ITO decreases with V1. In this case, capacitor Cfb is discharged and voltage decreases with a reduction in V_ITO. Consequently, the voltage Vst between capacitor C1 for data storage and capacitor Cfb decreases in accordance with the reduction in voltage of this capacitor Cfb. Thereafter, V1 drops to a predetermined voltage. This predetermined voltage is determined such that the amount of change in voltage Vst can be easily found as ΔV_st.

The reduction in voltage of V1 should by performed with a slope that is gradual in comparison to the rise or fall when other voltages change as illustrated, such that noise due to the unintentional flowing in and out of charge is minimized. For instance, by means of the actual testing apparatus, it is possible to set the gradient at 10⁶ to 10¹⁰V/seconds using a measurement rate of 1 MHz to 100 MHz.

It is possible to determine the properties of this drive circuit, that is, to determine the threshold voltage, by finding the ΔV_St, which is the amount of change in voltage V_st, when measuring with the testing apparatus of the present invention. Specifically, once the above-mentioned operation of V1 has been performed and a pre-determined voltage has been reached, the gate of transistor Q1 is turned on once again by Gate(n) to produce the V_st in the figure and then voltage ΔV_st is measured by reading the charge that has accumulated using an ammeter or a charge meter (not illustrated) connected to data line Data (m). When the amount of change in the voltage of V_ITO is ΔV_ITO, the measured charge is Qn=ΔV_stX(Cs+Cfb); therefore, ΔV_ITO is found from the resulting ΔV_st and the correlation of ΔV_ITO=ΔV_stX((C1+Cfb)/Cfb).

Vth here can be determined as the difference between the sum of the final value of V1 (shown as V1_ref1 in FIG. 2) and ΔV_ITO and V_st after the data has been set (shown as V_st1 in FIG. 2; this virtually coincides with V_st when the charge is read). That is,
Vth=(V1_ref1+ΔV_{—}ITO)−(V_st1) [Formula 1].
Consequently, the operating properties of the drive circuit of each pixel can be confirmed by determining whether or not the difference between the resulting Vth for each pixel and the reference potential is within a predetermined range. Furthermore, by means of another method, ΔV_st is monitored as V1 is changed and Vth can be determined from the difference between V1 when ΔV_st has been changed and V1 when the data were set, that is, before the change.

A p-type transistor is used for transistors Q1 and Q2 in the case of the current drive-type drive circuit shown in FIG. 3. In contrast to the above-mentioned voltage drive-type device, the resetting of capacitor Cfb is not necessary. The predetermined voltage is supplied to current supply line V2. Transistor Q1 is turned on by controlling gate signal line (n). By pre-applying a pre-determined voltage to data signal line Data (m), transistor Q2 is turned on. In this case, the voltage of V1 connected to the source of transistor Q2 is set higher than the gate.

Voltage V1 (Is) gradually falls from this state. Voltage V_ITO, which is the voltage of the electrode (ITO), also changes until transistor Q2 turns off. As described above, current flows out from retaining capacitor C1 to capacitor Cfb in this case. When the potential of source supply line V1 drops farther than the voltage at which the gate potential of transistor Q2 is turned off (threshold voltage Vth), a charge will not flow out from C1. Transistor Q1 is turned on in this state and the charge that has accumulated at retaining capacitor C1 is measured using an ammeter or a charge meter (not illustrated) connected to the data signal line (Data (m)). Moreover, the difference between the charge that has been fed (or written) at retaining capacitor C1 and the amount of charge that has been read is found for each pixel. In addition, the operation of the drive circuit of the pixels can be confirmed by determining whether or not this difference is within a pre-determined range.

Vth here can be determined as the difference between the value that is obtained by subtracting ΔV_ITO from the initial value of V1 (shown as V1_ref2 in FIG. 3) and the value when V_st is at its lowest (shown as V-st2 in FIG. 3. It should be noted that it coincides with V_st before reading the charge.) That is,
Vth=(V1_ref2−ΔV_ITO)−V_st2) [Formula 2]
Consequently, as in the above-mentioned examples, this Vth can be used as the parameter for confirming the operating properties of the drive circuit.

As is clear from the description relating to each of the above-mentioned examples, it is possible to find the value of Vth, which is the threshold value of transistor Q2, by one measurement using a testing means of the testing apparatus of the present invention; therefore, the present invention has an advantage in that measurement through-put is high when compared to conventional circuits.

The testing apparatus feeds back at 60 the threshold value Vth found based on the detected current or charge (that is, V_ITO) as the parameter design criterion for the preceding step of film formation, as previously described. This feedback 60 was previously used at semiconductor film formation step 50, as shown in FIG. 1. Consequently, threshold value Vth can serve as the criterion for setting the parameters of step 51 for thin film deposition and step 52 for annealing.

Of these film-forming steps 50, Vth is a parameter that can serve as a criterion for determining the film formation time in the first film deposition step 51. In another case, it can be concluded that there is too much in-plane fluctuation in Vth of the substrate because there is insufficient in-plane uniformity of the thin film, and the substrate position or plasma distribution during film formation can be changed using Vth as the criterion. Nevertheless, it is preferred that the feed back will give priority to the second annealing step 52, which is easily affected by the meter for the design parameters.

As previously mentioned, annealing is typically performed by laser annealing technology. The number of shots, energy density, and substrate temperature are examples of typical design parameters for laser annealing with an excimer laser. The irradiation time per unit of surface area replaces the number of shots as a design parameter for visible light solid lasers. Consequently, Vth is used as a criterion for determining these parameters. Energy density is the parameter most easily controlled, for both the excimer lasers and solid lasers. For instance, it is possible that crystallization by annealing will be insufficient when Vth as measured with the testing apparatus is higher than a predetermined range, or shows a tendency to be high although within a predetermined range. In this case, the parameter can be changed taking the magnitude of the measured Vth into consideration such that the energy density of radiation of the annealing light is high within a pre-determined range in order to increase the degree of crystallization.

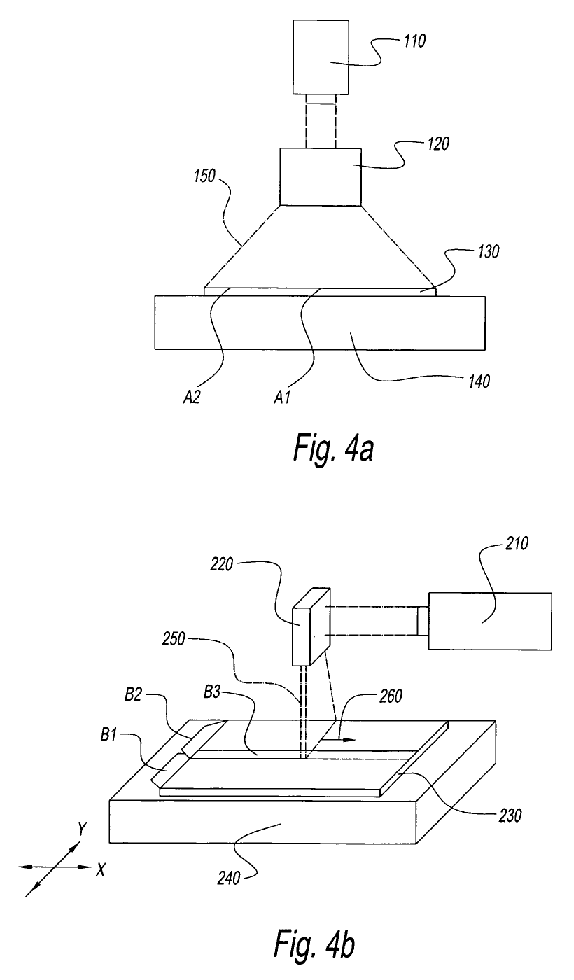

FIG. 4 is a rough sketch showing a structural example of a laser annealing device when the operating threshold value Vth is used as feedback, and different methods are illustrated in (a) and (b).

By means of an apparatus 100 in FIG. 4(a), the light reflected from laser light source 110 is irradiated over the entire width of the deposited thin film using a hologram, a mirror, or another optical system 120. A substrate 130 on which the thin film has been deposited is shown on a movable table 140. Laser light is diffused over a relatively wide area by optical system 120 (reference 150).

By means of this example, there is a difference, for instance, in the mobility between position A1 near the center and position A2 near the edge of the thin film due to the effect of laser irradiation; as a result, there is a chance that the threshold value voltage Vth of the thin film transistor of the drive circuit will be different for the pixels at these positions. In such cases, the settings of optical system 120 can be changed based on the threshold value information that has been fed back as previously described and the distribution of the quantity of light in the direction of width of the radiated light can be re-optimized such that there is no difference in mobility between positions A1 and A2. In this case, the threshold information that is used as a reference can serve as the average for multiple pixels at specific distances from one another in the direction of width.

Of course, changes are preferred whereby the energy density or number of shots, and the like, in the case of an excimer laser is optimized based on the threshold information as previously described when the threshold voltage Vth is within an appropriate range over the entire region on substrate 130. Moreover, when the difference in mobility is attributed in part to the thickness of the thin film, the parameters can be reset referring to the threshold information such that there will be no fluctuations that cause a difference in film thickness during film deposition step 51.

By means of an apparatus 200 in FIG. 4(b), the light reflected from a laser light source 210 is eventually irradiated through a hologram, a mirror, or another optical system 220 onto the deposited thin film (reference 250), but the optical system scans in such a way that the irradiated strips partially overlap. A substrate 230 on which the thin film has been deposited is placed on a movable table 240. Reference 260 in the figure shows the direction of scanning of the radiated light beam relative to substrate 230. The light reflected from optical system 220 is irradiated successively through strips B1 and B2, and B3 is the portion where these strips overlap.

By means of this example, it is possible that there will be a difference in the threshold voltage Vth between the pixels in regions B1 and B2 that do not contain B3 or between the pixels in regions B1 and B2 and those in B3. In such cases, the energy density, the number of shots, or another parameter for the irradiation of regions B1 and B2 can be changed based on the threshold information, or the optical properties of optical system 220 can be changed in such a way that the amount of light reflected in the width thereof is optimized as in the example of FIG. 4(a). That is, the present invention has an advantage in that even if at least a portion of a substrate is irradiated in the width thereof at different times, this irradiation can be relatively easily managed by a formula for making uniform the properties of the drive circuit on the panel substrate in the final product.

As previously mentioned, preferred embodiments of the present invention have been described in detail, but these are in the end only representations and can be altered or modified by persons skilled in the art. For instance, there are various parameters for film deposition or laser annealing other than those shown in these embodiments, and the present invention can be realized using these parameters. The present invention can also be used with annealing methods that do not employ a laser.

What is claimed is:

1. A system for manufacturing a display panel comprising a system for manufacturing a panel substrate as managed by a formula whereby a thin film of semiconductor materials is formed and drive circuits for pixels are formed; a testing unit for testing the resulting panel substrate; and a mounting device for mounting a display vehicle containing an organic EL or liquid crystal material on the tested panel substrate,
wherein said testing unit determines the threshold value of the drive voltage in the drive circuits of each of the pixels during testing.

2. The manufacturing system according to claim 1, wherein said threshold value serves as the criterion for determining the parameters for forming a thin film from the semiconductor materials of said system for manufacturing a panel substrate.

3. The manufacturing system according to claim 2, wherein said system for manufacturing a panel substrate comprises a means for depositing an amorphous thin film on a glass substrate and a laser annealer for annealing the deposited thin film as the means for forming a thin film of the semiconductor materials, and the threshold value serves as the criterion for determining the control parameters for at least the laser annealer.

4. The manufacturing system according to claim 3, wherein said laser annealer is set such that the irradiation conditions pertaining to at least part of the panel substrate are different from the irradiation conditions relating to the rest of the substrate in accordance with the threshold value.

5. The manufacturing system according to claim 3, wherein said threshold value is also used as a criterion for determining the parameters for film formation when the thin film is deposited.

6. The manufacturing system according to claim 1, wherein said manufacturing system is constructed such that the threshold value is automatically fed back to said system for manufacturing a panel substrate.

7. The manufacturing system according to claim 1, wherein said drive circuits comprise thin-film transistor elements for turning the pixels on and off; capacitors connected to the gates of the thin-film transistor elements, and electrical source connectors coming from the electrical source supply lines on the panel substrate and connected to the drain side of the thin-film transistor elements, and the testing unit comprises a means for retaining the charge at each capacitor and a means for detecting the charge flowing out from the capacitors and determining the threshold value when the potential of the electrical source connectors has changed.

8. The manufacturing system according to claim 7, wherein said testing unit detects the charge flowing from the capacitors through data lines that are set up such that they connect with the drive circuits on the panel substrate.

9. The manufacturing system according to claim 7, wherein said drive circuit on the panel substrate comprises additional load capacitors that are connected to the gate and receive the charge flowing out from the capacitors.

10. A method for manufacturing a display device comprising:
manufacturing a panel substrate controlled by a formula, which in turn comprises: forming a thin film of a semiconductor material, and forming drive circuits of pixels;
testing of the resulting panel substrate; and
mounting a display vehicle on the tested substrate,
wherein said testing step comprises: determining the threshold value of the drive voltage in the drive circuits of each pixel during testing, and providing the determined threshold value information to the step for manufacturing a panel substrate such that it serves as the criterion for determining the parameters for the manufacture of the panel substrate.

11. The manufacturing method according to claim 10, wherein said step for the formation of a thin film of the semiconductor materials comprises: depositing of the semiconductor materials, and laser annealing the deposited semiconductor materials, wherein said threshold value is used as the criterion for determining the parameters of at least the step of laser annealing.

12. The manufacturing method according to claim 12, wherein said step for providing the threshold value information to the means for manufacturing the panel substrate comprises a step for automatically feeding back the threshold value information.

13. The manufacturing method according to claim 10, wherein said drive circuits comprise thin-film transistor elements for turning the pixels on and off; capacitors connected to the gates of the thin-film transistor elements; and electrical source connectors coming from the electrical source supply lines on the panel substrate and connected to the drain side of the thin-film transistor elements, and the testing unit comprises: a means for retaining the charge at each capacitor, a first detector for detecting the charge flowing out from the capacitors and determining the threshold value when the potential of the electrical source connectors has changed, and a second detector for detecting the charge that has flowed out from the capacitors and for determining the threshold value.

14. The testing apparatus according to claim 13, wherein said change in the potential of the electrical source connectors occurs at such a speed that charge does not flow into or out from the gate of the thin-film transistor element.

15. A testing apparatus for testing the operation of the drive circuit elements of each pixel on a display panel substrate comprising a first thin-film transistor element for switching pixels on and off; capacitors connected to the gate of the first thin-film transistor element; and electrical source connectors extending from the electrical source supply lines on the display panel to the drain side of the first thin-film transistor element, wherein said testing apparatus comprises
a means for retaining a charge at the capacitors;
a means for gradually changing the potential of the electrical power connectors so that a charge flows out from the capacitors;
a detector for detecting the charge flowing out from the capacitors and determining the threshold value of the drive voltage of the first thin-film transistor; and
a means for outputting the determined threshold value information.

16. The testing apparatus according to claim 15, wherein said drive circuit has a second thin-film transistor between the gate of the first thin-film transistor and the data line on the display panel substrate, and the means for detecting the charge comprises a means for switching and controlling the second thin-film transistor such that the charge flowing out from the capacitors is guided to the data line.

17. The testing apparatus according to claim 16, wherein said gate of the second thin-film transistor is connected to the gate line on the display panel substrate, and the second transistor is controlled by this gate line.

18. The testing apparatus according to claim 15, wherein said drive circuits are constructed such that the first and second thin-film transistors are p-type gates, and wherein said drive circuits comprise the gate of the first thin-film transistor and additional load capacitor connected to the pixel electrode on the drain side of the first thin-film transistor, and further comprise a means for controlling the first thin-film transistor such that the load capacitor is reset.

19. The testing apparatus according to claim 15, wherein said drive circuits are constructed such that the first and second thin-film transistors are n-type gates, and wherein said drive circuits comprise a controller in order to keep the potential of the gate lines at a constant value.
